(19) United States
(12) Patent Application Publication
(10) Pub. No.: US 2010/0044579 A1
(43) Pub. Date: Feb. 25, 2010

(54) APPARATUS

(75) Inventors: Timothy Andrew James Holmes, Berkshire (GB); Mervyn Howard Davis, Sussex (GB)

Correspondence Address: Patent Docket Department;Armstrong Teasdale LLP, One Metropolitan Square, Suite 2600, St. Louis, MO, 63102-2740, US

(73) Assignee: NORDIKO TECHNICAL SERVICES LIMITED, Havant Hampshire, GB (GB)

(21) Appl. No.: 12/304,251

(22) PCT Filed: Feb. 15, 2008
(86) PCT No.: PCT/GB2008/050098

§ 371 Date: Oct. 30, 2009

(30) Foreign Application Priority Data
Feb. 15, 2007 (GB) 0703044.8

(51) Int. Cl. H01J 37/04; H01J 27/00

(52) U.S. Cl. 250/423 R; 315/500

(57) ABSTRACT

An apparatus for accelerating an ion beam, comprising at least one electrode mounted in a moveable mount.

### BACKGROUND OF THE INVENTION

The present invention relates to apparatus for ion beam acceleration. More specifically, it relates to apparatus for low beam voltage ion acceleration for use in ion beam techniques such as sputtering. In addition, the present invention relates to an apparatus for generating a beam of charged particles.

Ion beams have been used for used for many years in the production of components in the micro-electronics industry and magnetic thin film devices in the storage media industry. In particular, ion beams are used in the production of thin film heads for hard disk drives. The quality of layer interface is important in the fabrication of thin film magnetic sensors used in the storage media industry.

Ion beams may be used in a number of ways to modify the structure of a thin film for example by sputter deposition, sputter etching, milling or surface smoothing. In this context gridded broad ion beam sources are considered more appropriate than non-gridded sources for providing a useable monochromatic ion beam flux.

In the semiconductor, thin film and materials industries ion implantation is a well known technique used to embed ions into the crystal lattice of materials to modify their electrical properties. Many fabricated micro- and nano-devices rely on the detailed nature of thin film interfaces to enhance efficient operation. It will therefore be understood that the ability to generate atomically smooth surfaces plays an important role in device and thin film fabrication techniques.

The manufacturing processes used in fabrication of thin film magnetic sensors such as hard disc drive read heads are broadly defined by two distinct phases. The first phase, which is commonly referred to as wafer fabrication, deals with the formation of the sensors on a flat wafer. This phase, which is also known as the front end process, revolves around the sequential application and patterning of thin films on round or square wafers. The front-end process uses planar epitaxial or deposition techniques to build the nano-structure that becomes the active device. The planar techniques build the nano-structure. The size of the wafer varies but the largest is generally about 200 mm in diameter.

Once the devices are formed on the wafer as on array, the wafer is cut and the second phase, which may be referred to as slider fabrication, or as the back-end process commences. Here, the wafers are cut into strips called row bars and assembled onto platens. The back-end processes nano-machine the surfaces that were orthogonal to the wafer plane. Both the front and back-end processes require low power and high power ion milling applications.

In a typical ion beam source (or ion gun) a plasma is produced by admitting a gas or vapour to a low pressure discharge chamber. For a dc source, the chamber contains a heated cathode and an anode which serves to remove electrons from the plasma and to give a surplus of positively charged ions which pass through a screen grid or grids into a target chamber which is pumped to a lower pressure than the discharge chamber. Ions are formed in the discharge chamber by electron impact ionisation and move within the body of the ion gun by random thermal motion.

Modern ion sources are more commonly excited using high frequency electrical discharges other than by an arc. Radio frequencies ranging from about 500 kHz to about 60 MHz are employed although those in the range of from about 13 MHz to about 60 MHz may be more commonly employed. There are also devices which use microwave excitation.

The plasma will thus exhibit positive plasma potential which is higher than the potential of any surface with which it comes into contact. Various arrangements of electrodes can be used, the potentials of which are individually controlled. In a multi-grid system the first electrode encountered by the ions is usually positively biased whilst the second electrode is negatively biased. A further grid may be used to decelerate the ions emerging from the ion source so as to provide a collimated beam of ions having more or less uniform energy. For ion sputtering a target is placed in the target chamber where this can be struck by the beam of ions, usually at an oblique angle, and the substrate on to which material is to be sputtered is placed in a position where sputtered material can impinge on it. When sputter etching, milling or surface smoothing is to be practised the substrate is placed in the path of the ion beam.

Hence, in a typical ion gun, an ion arriving at a multi-aperture extraction grid assembly first meets a positively biased electrode. Associated with the grid is a plasma sheath. The potential difference between the plasma and the grid is dropped across this sheath. This accelerating potential will attract ions in the sheath region to the first grid. Any ion moving through an aperture in this first grid, and entering the space between the first, positively biased grid, and the second, negatively biased, grid is strongly accelerated in an intense electrical field. As the ion passes through the aperture in the second grid and is in flight to the earthed, conductive, target it is moving through a decelerating field. The ion then arrives at an earthed target with an energy equal to the potential of the first, positive, grid plus the sheath potential.

Hence, a conventional ion gun comprises a source of charged particles which are accelerated through an externally applied electric field created between a pair of grids. Conventionally, for low energy ion beam production, three grids are used, (although more can be used) the first being held at a positive potential, the second being held at a negative potential adjusted to give the best divergence, and the third, if present, at earth potential, i.e. the potential of the chamber in which the beam is produced.

For production of thin film magnetic devices the process constraints are diffraction limited such that it is difficult to achieve the necessary ion beam size. As the thin film magnetic devices become smaller the constraints on the process become more demanding and it is difficult to achieve good quality low energy ion beams. For processes that require high power levels across a relatively large wafer area there are a number of issues that present technical challenges. One such challenge is that such applications require a high integrated beam current and relatively low beam voltage. Another challenge is that the divergence characteristics of the beam need to be very good. These two attributes are difficult to achieve with beam energies below 1000 V, but have been successfully demonstrated using techniques described in UK patent applications 0612915.9 and 0622788.8 and which are incorporated herein by reference.

For processes that require high milling rates at low beam energy, beam uniformity is known to decay as the accelerator ages. One significant reason for the decay in uniformity is physical instability of the accelerator caused by the movement of the grids within the accelerator. The grids that comprise the ion accelerator grids have various parameters that are optimised for a specific application. One of these parameters is the inter-electrode separation and another is the aperture alignment. Any distortion or misalignment in inter-electrode separation and/or aperture alignment occurring will in turn cause a significant perturbation of the beam uniformity resulting in loss of beam collimation. This perturbation will ultimately have a negative affect on the ability of the ion accelerator to carry out both high and low power applications.

The distortion of the grid dimensions or mounting position arises from thermal stress. Although there is not a very large heat load on the accelerator, it is essentially isolated within a vacuum environment. It is relatively easy to position the first grid by providing fixed mounts around its periphery; the second and third grids are positioned in a thermally isolated environment within a vacuum and therefore can only dissipate heat through radiation. When misalignment or distortion of the grids occurs it is necessary to halt processing so that the grids can be realigned, resulting in a low mean time to maintenance of several days, which in turn results in costly down time of the processing equipment.

For ease of reference the grids will hereinafter be referred to as an electrode.

One known proposal to dissipate heat from the electrodes and minimise distortions, and thus increase the mean time to maintenance, is it to provide channels within the electrodes, through which fluid can be passed to actively cool the electrodes. Whilst these arrangements may address the problem, for many applications it is considered to be prohibitively costly.

The present invention seeks to overcome the problems associated with the prior art and provide a system for producing an ion beam having low beam divergence as a result of thermal induced stress on the electrodes, which results in misalignment of the electrodes in a cost effective manner.

According to a first aspect of the present invention, there is provided an apparatus for accelerating an ion beam comprising at least one electrode mounted in a movable mount. In a preferred arrangement the apparatus includes a plurality of electrodes at least one of which is mounted in a moveable mount.

In a further preferred arrangement, the apparatus comprises: a first electrode having at least one aperture therethrough; a second electrode located such that it is adjacent to and spaced from the first electrode and having at least one aperture therethrough; and a third electrode located such that it is adjacent to and spaced from the second electrode and having at least one aperture therethrough, said at least one apertures in each electrode being aligned with corresponding apertures in the other electrodes; and wherein at least one of the first electrode, the second electrode and the third electrode is mounted in a moveable mount. Most preferably, each of the electrodes is mounted in a moveable mount.

By “moveable mount” we mean that the mount may be moveable translationally, i.e. the position of the mount and hence the electrode within the assembly may be moved relative to the assembly and/or the motion may be radial, that is to say it may expand outwardly to accommodate any expansion in the electrode and thereby prevent buckling thereof.

Where a plurality of electrodes is present, the moveable mounts may enable each electrode to be moved independently.

Where a plurality of moveable mounts are present, the use of moveable mounts for some or all of the electrodes enables constant beam stability and improved beam uniformity to be achieved even under the influence of thermal stress generated in the apparatus. This ultimately results in longer mean time to maintenance and reduces costly downtime of the accelerator.

Where a plurality of electrodes are present, the moveable mounts are arranged to maintain alignment of each of said apertures thereby providing improved stability of aperture alignment and inter-electrode separation.

Any suitable moveable mount may be used. In one arrangement, it may be a thermally isolated mount. In a preferred arrangement, the mount is a radial kinematic mount. Such mounts are known from optical applications. Where the electrodes are the first, second and third electrodes detailed above, the first electrode, may be a beam forming electrode, the second electrode may be an extraction electrode and the third electrode may be a ground electrode. Additionally or alternatively, the first electrode may be a diverging electrostatic lens and the third electrode may be a focusing electrostatic lens. In this arrangement, diverging and focusing electrostatic lenses are provided which result in highly collimated beams.

The accelerator of the present invention may be used in an apparatus for the production of charged particle beams and thus according to a second aspect of the present invention there is provided an apparatus for the production of charged particle beams comprising a plasma chamber, means for generating in the plasma chamber a plasma comprising particles of a first polarity and oppositely charged particles of a second polarity; means for restraining particles of the first polarity in the plasma chamber and an accelerator according to the above first aspect wherein the first electrode contacts the plasma.

The invention is described further hereinafter, by way of example only, with reference to the accompanying drawing, in which:

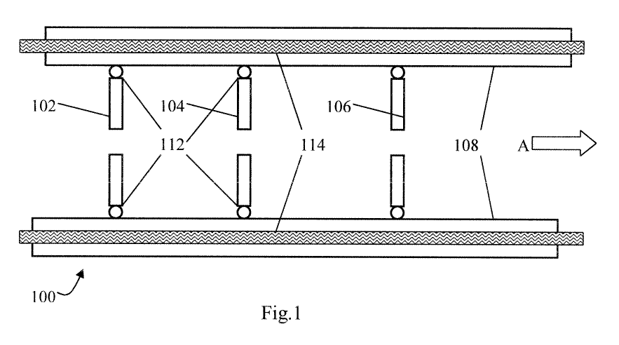

FIG. 1 is a cross section of an electrode arrangement according to the present invention;

As illustrated in FIG. 1, the present invention provides an ion accelerator 100 in the form of a triode. The triode arrangement includes a first beam forming electrode 102, a second extraction electrode 104 and a third electrode 106 known as a ground electrode. All the electrodes have apertures therethrough and each aperture is planar and has circular or rotational symmetry about the centre of the apertures. The electrodes are arranged in series such that their apertures are substantially aligned. The electrodes 102, 104 and 106 are mounted to a body portion 108 of the accelerator 100.

In order to provide stability against thermal stress produced in the accelerator each electrode is mounted to the body portion 108 of the accelerator 100, by means of a mount 112, 113 and 114. Each mount 112, 113 or 114 is arranged to provide thermal isolation of each electrode from the body portion 108 of the accelerator 100. The extraction electrode 104 and ground electrode 106, can be positioned in a vacuum environment, such as a vacuum chamber 110 and are thermally isolated from the beam forming electrode 102. Alternatively all three electrodes can be positioned in a vacuum environment.

The mounts 112, 113 and 114 are arranged such that when the electrodes 102, 104 and 106 and body portion heat up, they allow for radial movement of each electrode both relative to one another and relative to the body 108 of the accelerator 100. In this regard, the mount is said to have two degrees of freedom. Such a mount is generally known as radial kinematic mount. As the electrodes and the accelerator heat up, the mounts permit radial expansion of the electrodes which prevent the electrodes from buckling under the influence of thermally induced stress.

The, or each, electrode may be of any suitable geometry and may be of the configuration described in GB0612915.9 and GB0622788.7 which are incorporated herein by reference. The electrodes may include bevelled, cut-away portion or unbevelled aperture profiles. The apertures may be of any suitable shape such as circular.

In the preferred arrangement of the present invention, the final beam energy extracted from the accelerator 100 is defined by the difference in potential between the beam forming electrode 102 and the ground electrode 106 and the beam current is defined by the difference in potential between the beam forming electrode 102 and the extraction electrode 104. Assuming that the ground electrode 106 is fixed at a ground potential then the potential of the beam forming electrode 102 is also fixed. It follows therefore that the extraction electrode 104 potential can be fixed to any desired value within the constraints of beam collimation requirements. This type of accelerator is termed an accel-decel accelerator as the beam is first accelerated strongly and then retarded (decelerated) almost as strongly.

1. An apparatus for accelerating an ion beam, comprising at least one electrode mounted on a moveable mount, wherein the moveable mount is arranged to permit radial expansion of the at least one electrode.

2. An apparatus according to claim 1 wherein the apparatus includes a plurality of electrodes at least one of which is maintained in a moveable mount.

3. An apparatus according to claim 1 comprising:
a first electrode having at least one aperture therethrough;
a second electrode located such that it is adjacent to and spaced from the first electrode and having at least one aperture therethrough;
and a third electrode located such that it is adjacent to and spaced from the second electrode and having at least one aperture therethrough,
said at least one apertures in each electrode being aligned with corresponding apertures in the other electrodes; and wherein at least one of the first electrode, the second electrode and the third electrode is mounted in a moveable mount.

4. An apparatus according to claim 3 wherein each electrode is mounted in a moveable mount.

5. An apparatus according to claim 4, wherein moveable mount is arranged such that in use the alignment of each of said apertures.

6. An apparatus according to claim 1, wherein the mount is a thermally isolated mount.

7. An apparatus according to claim 1, wherein the mount is a radial kinematic mount.

8. An apparatus according to claim 1, further comprising a body portion and wherein the said moveable mount is attached to said body portion and thermally isolated threrefrom.

9. An apparatus for the production of charged particle beams comprising a plasma chamber, means for generating in the plasma chamber a plasma comprising particles of a first polarity and oppositely charged particles of a second polarity; means for restraining particles of the first polarity in the plasma chamber and an accelerator according to claim 1 wherein the at least one electrode contacts the plasma.
